(19) United States
(12) Patent Application Publication
(10) Pub. No.: US 2023/0306147 A1
(43) Pub. Date: Sep. 28, 2023

(54) Advances to Through-Thickness Reinforced Composite Analysis Capabilities

(71) Applicant: The Boeing Company, Chicago, IL (US)

(72) Inventors: Joseph D. Schaefer, Richmond Heights, MO (US); Brian P. Justusson, Saint Peters, MO (US)

(21) Appl. No.: 17/689,563

(22) Filed: Mar. 8, 2022

(51) Int. Cl. G06F 30/15; G06F 30/17; G06F 30/23

(52) U.S. Cl. CPC G06F 30/15; G06F 30/17; G06F 30/23

(57) ABSTRACT

An example method includes determining analytical material properties indicative of an effective fracture behavior of a through-thickness reinforcement. The method also includes obtaining data defining a cohesive formulation within a finite element analyzer. The cohesive formulation is representative of the through-thickness reinforcement, and the data defining the cohesive formulation is derived from the analytical material properties. The method further includes generating a finite element model for the composite structure. The composite structure includes the through-thickness reinforcement, and the finite element model represents the through-thickness reinforcement using the cohesive formulation. The method also includes analyzing a mechanical performance of the composite structure using the finite element analyzer and the finite element model, and outputting data indicative of the mechanical performance of the composite structure.

### FIELD

The present disclosure relates generally to a manufacturing system for composite structures and, in particular, to a method, apparatus, and system for designing and analyzing composite structures.

### BACKGROUND

Composite materials are widely used in the aircraft industry. Composite materials such as carbon fiber reinforced polymers (CFRPs) have a high strength-to-weight ratio as compared to metals such as aluminum and have a level of stiffness making these composite materials suitable for use to form aircraft structures. The structures include, for example, skin panels, stringers, ribs, wings, fuselage sections, passenger doors, floor boards, spars, frames, bulkheads, doublers, and other aircraft structures. Unitized composite structures utilizing advanced manufacture processes to remove part-to-part bondlines, interfaces, and discrete terminations via the use of resin infusion, co-curing, and through-thickness reinforcement can also provide improved strength-to-weight ratios compared to legacy design approaches which rely on testing with limited predictive modeling and analyses. Further, it is difficult to analytically predict the mechanical performance of unitized composite structures for use and deployment in design substantiation and certification.

Computer-aided design (CAD) systems are commonly used in designing composite structures. CAD systems can create three-dimensional models of composite structures. The CAD models can be used to select designs for manufacturing or analysis.

A three-dimensional model of a composite structure can be converted into a form from which the analysis of the strength, stiffness, and other performance of the composite structures can be determined. This analysis can take the form of a finite element analysis (FEA) of the composite structure.

Current modeling and analysis of composite aircraft structures are not always as accurate as desired. As a result, testing of prototypes of aircraft structures is often performed in addition to FEA analysis. The prototype testing is commonly used for airworthiness certification. If improvements to the mechanical performance of a design are desired, the design, modeling, manufacturing, and testing processes can be repeated in an effort to identify a better solution. Such efforts can involve great expense and cost to schedule. It also difficult to change solutions for a sub-component of a structure after the design for the structure has been finalized.

Composite structures are susceptible to translaminar failure modes (e.g., delamination/disbond) in which there is a rapid deterioration of load carrying capability due to an architectural feature separating from the structure. Due to certification requirements for aircrafts, the overall structure of some aircraft parts must retain residual strength for a full disbond of an architectural feature. To meet this requirement, bondlines of aircraft parts are reinforced with fasteners. For instance, fasteners are commonly used along stringer flanges of composite spars. These fasteners add weight to the aircraft, increase part counts, increase touch work, and add uncertainty to the build process - requiring extensive inspection during and after manufacturing. Additionally, fastened structures can require a high frequency of maintenance cycles due to damage that can occur in the fasteners or in areas surrounding the fasteners. Additionally, in some applications, aircraft structures are required to resist pressure load, which is a through-thickness loading. For instance, in fuselage applications, aircraft structures are required to resist pressure loading.

There is a need to develop novel design concepts which decrease the use of fasteners, improve through-thickness load carrying capacity, and improve overall maintenance/sustainability. Unitized composite structures provide this capability, and may take the form of multiple through-thickness reinforced material forms (e.g., stitching, z-pinning, flocking, three-dimensional weaves, etc.).

### SUMMARY

In one example, a method for designing a composite structure is described. The method includes determining analytical material properties indicative of an effective fracture behavior of a through-thickness reinforcement. The analytical material properties include a penalty stiffness, a cohesive strength, and a strain energy release rate. In addition, the method includes obtaining data defining a cohesive formulation within a finite element analyzer. The cohesive formulation is representative of the through-thickness reinforcement, and the data defining the cohesive formulation is derived from the analytical material properties. The method further includes generating a finite element model for the composite structure. The composite structure includes the through-thickness reinforcement, and the finite element model represents the through-thickness reinforcement using the cohesive formulation. The method also includes analyzing a mechanical performance of the composite structure using the finite element analyzer and the finite element model. And the method includes outputting data indicative of the mechanical performance of the composite structure.

In another example, a computing system is described. The computing system is configured for performing a set of acts. The set of acts includes determining analytical material properties indicative of an effective fracture behavior of a through-thickness reinforcement. The analytical material properties include a penalty stiffness, a cohesive strength, and a strain energy release rate. The set of acts further includes obtaining data defining a cohesive formulation within a finite element analyzer. The cohesive formulation is representative of the through-thickness reinforcement, and the data defining the cohesive formulation is derived from the analytical material properties. The set of acts also includes generating a finite element model for a composite structure. The composite structure includes the through-thickness reinforcement, and the finite element model represents the through-thickness reinforcement using the cohesive formulation. The set of acts also includes analyzing a mechanical performance of the composite structure using the finite element analyzer and the finite element model, and outputting data indicative of the mechanical performance of the composite structure.

In another example, a non-transitory computer-readable medium is described. The non-transitory computer-readable medium has stored therein instructions that are executable to cause a computing system to perform functions. The functions include determining analytical material properties indicative of an effective fracture behavior of a through-thickness reinforcement. The analytical material properties include a penalty stiffness, a cohesive strength, and a strain energy release rate. The functions further include obtaining data defining a cohesive formulation within a finite element analyzer. The cohesive formulation is representative of the through-thickness reinforcement, and the data defining the cohesive formulation is derived from the analytical material properties. The functions also include generating a finite element model for a composite structure. The composite structure includes the through-thickness reinforcement, and the finite element model represents the through-thickness reinforcement using the cohesive formulation. The functions also include analyzing a mechanical performance of the composite structure using the finite element analyzer and the finite element model, and outputting data indicative of the mechanical performance of the composite structure.

The features, functions, and advantages that have been discussed can be achieved independently in various examples or may be combined in yet other examples further details of which can be seen with reference to the following description and figures.

### BRIEF DESCRIPTION OF THE FIGURES

The novel features believed characteristic of the illustrative examples are set forth in the appended claims. The illustrative examples, however, as well as a preferred mode of use, further objectives and descriptions thereof, will best be understood by reference to the following detailed description of an illustrative example of the present disclosure when read in conjunction with the accompanying figures, wherein:

FIG. 1 is an example computing system.

FIG. 2 is a conceptual illustration of flatwise tension testing and associated data.

FIG. 3 is a conceptual illustration of compiled flatwise tension data.

FIG. 4 is a conceptual illustration of a stitch behavior model.

FIG. 5 is a conceptual illustration of fracture toughness testing.

FIG. 6 is a conceptual illustration of compiled fracture toughness data.

FIG. 7 is a conceptual illustration of an effective stitch response model.

FIG. 8 is a conceptual illustration of accuracies of different effective stitch response models.

FIG. 9 shows a flowchart of a method, according to an example.

FIG. 10 shows an additional operation for use with the method shown in FIG. 9.

FIG. 11 shows additional operations for use with the method shown in FIG. 9.

FIG. 12 shows additional operations for use with the method shown in FIG. 9.

FIG. 13 shows additional operations for use with the method shown in FIG. 9.

FIG. 14 shows an additional operation for use with the method shown in FIG. 9.

FIG. 15 shows an additional operation for use with the method shown in FIG. 9.

FIG. 16 shows an additional operation for use with the method shown in FIG. 9.

FIG. 17 is a schematic illustrating a conceptual partial view of an example computer program product.

### DETAILED DESCRIPTION

Disclosed examples will now be described more fully hereinafter with reference to the accompanying figures, in which some, but not all of the disclosed examples are shown. Indeed, several different examples may be provided and should not be construed as limited to the examples set forth herein. Rather, these examples are provided so that this disclosure will be thorough and complete and will fully convey the scope of the disclosure to those skilled in the art.

Current strategies for ensuring bondline integrity in composite structures are costly and can also limit structural design. The use of through-thickness reinforcements, such as stitching and z-pins, can provide interlaminar/bondline reinforcement to composite structures with minimal damage to the composite structure and limited reduction in strength, stiffness, and material quality.

Although through-thickness reinforcements are an advantageous alternative to fasteners, existing approaches for designing through-thickness reinforced composite structures and evaluating the mechanical performance of such structures are costly and time-consuming. For instance, when designing a through-thickness reinforced composite structure, there are various design choices to be made, such as the type of reinforcement, the location of the reinforcement, pattern of the reinforcement, and the orientation of the reinforcement. After settling on a design, a prototype is then manufactured for ensuring that load requirements are met. This testing can require a significant cost investment (e.g., significant time, schedule, traveled risk, and/or material). Further, even if the prototype satisfies load requirements, the results of the test often do not indicate whether the solution is optimal.

Disclosed herein are methods and systems to address this and potentially other issues. An example method involves determining analytical material properties indicative of an effective fracture behavior of a through-thickness reinforcement. For instance, a penalty stiffness, a cohesive strength, and a strain energy release rate are determined. The analytical material properties can be determined based on modeling failure of the through-thickness reinforcement within a host structure using a local representative model, experimental data, or both. These analytical material properties are then used to derive data defining a cohesive formulation within a FEA.

The method also involves generating a finite element model for a composite structure. The composite structure includes the through-thickness reinforcement, and represents the through-thickness reinforcement using the cohesive formulation. After generating the finite element model, mechanical performance of the composite structure is analyzed using the FEA. In some examples, the FEA uses novel material models implemented in the form of subroutines which are coded as the cohesive formulation. Based on the analysis, a computing system outputs data indicative of the mechanical performance of the composite structure.

In some examples, modeling failure of the through-thickness reinforcement within a host structure using a local representative volume model allows for developing a material model than can be applied to a lower order element, such as a truss, beam, or shell while still being able to capture discrete damage events. Unlike existing solutions, this approach can be used to analytically explore the design space of the through-thickness reinforcement. For instance, an engineer can evaluate multiple stitch patterns, architectures, thread types, etc., using the local representative volume model, and then homogenize the response of a particular through-thickness reinforcement configuration into a cohesive formulation (e.g., a cohesive zone model). The cohesive formulation can be inserted into a finite element model, and may be scaled to a desired size for a structural application. By working with native solver capability (e.g., Abaqus, LS-DYNA, NASTRAN, etc.), the approach maintains the ability to couple with advanced damage and failure constitutive models/subroutines for predicting static strength, stiffness, fatigue performance (durability), and residual strength after a damage event or fatigue (damage tolerance).

In some examples, the local representative volume model analyzes failure of a through-thickness reinforcement in three-dimensions. Based on this three-dimensional modeling, analytical material properties are determined that allow for representing the through-thickness reinforcement in two-dimensions as a cohesive formulation. Representing the through-thickness reinforcement as a cohesive formulation rather than a three-dimensional element can greatly reduce the computational expense of analyzing mechanical performance of a composite structure that includes the through-thickness reinforcement. In addition, representing the through-thickness reinforcement as a cohesive formulation provides the ability to include multiple cohesive laws in the same location to account for multiple failure modes/material behaviors in the same location. Any form of cohesive law can be used, such as bi-linear, tri-linear, n-linear, non-linear, or discrete/parameterized).

Local representative volume model analysis is inherently not scalable to large length scales, and requires far higher analysis run times to complete. The disclosed systems and methods allow for scalability - the disclosed cohesive formulations can be used to analyze larger (custom/tailored) length scales appropriate for failure modes and structure length scales of interest, from individual small coupon through full configured structure (multiple frames and multiple feet by multiple feet) in a manner that maintains predictive accuracy, reduces the number of lower level tests required to populate the finite element model (the scaled model can be generated solely based on outputs of the local representative volume model, for example), and cover a large domain of length scales in a suitable/practical amount of analysis computation time (i.e., the finite element model can be analyzed in minutes to hours, rather than months) using local or high performance computing resources.

Various other features of these systems and methods are described hereinafter with reference to the accompanying figures.

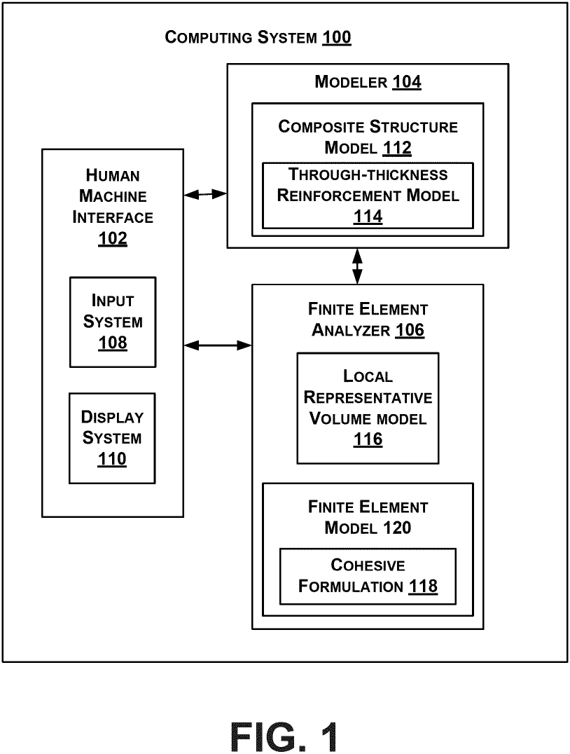

Referring now to FIG. 1, FIG. 1 is an example computing system 100. In this disclosure, the term “computing system” means a system that includes at least one computing device. In some instances, a computing system can include one or more other computing systems.

Computing system 100 can take the form of a client device (e.g., a computing device that is actively operated by a user), a server, cloud computing device, or some other type of computational platform. In some examples, computing system 100 can take the form of a desktop computer, laptop computer, tablet computer, smartphone, wearable computing device (e.g., AR glasses), or other type of device.

As such, computing system 100 can include a processor and a memory. The processor can be a general-purpose processor or special purpose processor (e.g., a digital signal processor, application specific integrated circuit, etc.). The processor can be configured to execute instructions (e.g., computer-readable program instructions including computer executable code) that are stored in the memory and are executable to provide various operations described herein.

The memory can take the form of one or more computer-readable storage media that can be read or accessed by the processor. The computer-readable storage media can include volatile and/or non-volatile storage components, such as optical, magnetic, organic or other memory or disc storage, which can be integrated in whole or in part with the processor. The memory is considered non-transitory computer readable media. In some examples, the memory can be implemented using a single physical device (e.g., one optical, magnetic, organic or other memory or disc storage unit), while in other examples, the memory can be implemented using two or more physical devices.

Computing system 100 can be in communication with another device over a communication link. The communication link can take the form of any wired connection (e.g., Ethernet) or wireless connection (e.g., Bluetooth®) over which computing system 100 and the other device can engage in communication.

In operation, computing system 100 can perform any of the functions described herein. For instance, computing system 100 can modeling failure of a through-thickness reinforcement, determine analytical material properties indicative of an effective fracture behavior of the through-thickness reinforcement, obtain data defining a cohesive formulation within a FEA, generate a finite element model of a composite structure including the through-thickness reinforcement, analyze a mechanical performance of the composite structure, and/or output data indicative of the mechanical performance of the composite structure.

As shown in FIG. 1, computing system 100 includes a human machine interface 102, a modeler 104, and a FEA 106. Human machine interface 102 includes an input system 108 and a display system 110. Input system 108 and display system 110 facilitate interaction with modeler 104 and FEA 106. Input system 108 is a physical hardware system and can include at least one of a mouse, a keyboard, a trackball, a touchscreen, a stylus, a motion sending input device, a wearable glove, or some other suitable type of input device. Display system 110 is a physical hardware system and can include one or more display devices in which a graphical user interface can be displayed.

Modeler 104 can include a CAD system, such as Solidworks available from Dassault Systemes SE, Catia available from Dassault Systemes SE, AutoCAD available from Autodesk, Inc., NX available from Siemens Product Lifecycle Management Software Inc., CREO available from PTC, Inc., Abaqus/CAE available from Dassault Systemes, Hyperworks available from Altair Engineering, Inc., LS DYNA available from ANSYS, or other suitable software products.

Modeler 104 can generate a three-dimensional model of a composite structure that represents a structural geometry of the composite structure. The composite structure can be a component of a mobile platform, a stationary platform, a land-based structure, an aquatic-based structure, a space-based structure, an aircraft, a commercial aircraft, a rotorcraft, a surface ship, a tank, a personnel carrier, a train, a spacecraft, a space station, a satellite, a submarine, an automobile, a power plant, a bridge, a dam, a house, a manufacturing facility, a building, or some other suitable type of product having a composite structure. The composite structure can take a number of different forms. For example, the composite structure can be a skin panel, a fairing, an engine housing, a stringer, a door, a wing, a panel, a skin panel, a composite stringer stiffened panel, a frame, a doubler, a spar, or other suitable types of composite structures.

In operation, based on input received via input system 108, modeler 104 can convert a three-dimensional model (e.g., a CAD model) of one or more composite structures into a composite structure model 112 that is in a form such that structural analysis in the form of finite element analysis can be performed on the composite structure model. Composite structure model 112 can include a set of one or more component models. In one example, composite structure model 112 is a mesh comprised of elements that form the shape of a composite structure. Components within the composite structure are defined by the elements and their interconnections at nodes. The elements can be three-dimensional elements. These elements can include at least one of a shell, solid, a cohesive element of zero-thickness, a cohesive element of a defined thickness, a tetrahedral element, a pentahedral element, a hexahedral element, a four-node tetrahedral element, a ten-node tetrahedral element, a three node shell element, or other suitable types of elements applicable to finite element analysis. The elements forming the mesh can have properties such as an orientation, a thickness, a coefficient of expansion, a density, a Young’s modulus, a shear modulus, a Poisson’s ratio, a strength, a fracture energy/toughness, and other suitable properties.

Modeler 104 can also insert one or more through-thickness reinforcements into composite structure model 112 based on input received by way of input system 108. The through-thickness reinforcements can be assigned any type, location, angle, size, etc. based on input provided by way of input system 108. Examples of through-thickness reinforcements include a z-axis reinforcement a stitch, a pen, a fastener, or some other type of reinforcement. Within composite structure model 112, a through-thickness reinforcement is represented by a through-thickness reinforcement model 114. Inserting a through-thickness reinforcement into composite structure model 112 can involve assigning elements as corresponding to through-thickness reinforcement model. 114. Through-thickness reinforcement models, as well as techniques for analyzing composite structure models having embedded through-thickness reinforcement models are described in U.S. Pat. Application No. 16/584,119, entitled “Reinforced Composite Structure Analysis System,” which is hereby incorporated herein by reference.

A through-thickness reinforcement model can model response of an embedded through-thickness reinforcement to a set of structural loads. A through-thickness reinforcement model can define properties of a reinforcement. These properties can include, for example, a coefficient of expansion, a density, a Young’s modulus, a shear modulus, a Poisson’s ratio, and other suitable properties. These properties can be used to generate reinforcement elements that placed into a mesh. Further, an embedded reinforcement model can also include other information such as dimensions (e.g., a cross-sectional area).

The properties can be generated using a sensor system (not shown) that detects responses of a through-thickness reinforcement to a set of structural loads. The sensor system can include a computed tomography (CT) scanner, x-ray scanner, or other type of sensor system, for instance. The data may be indicative of a nonconformance such as a deformation or a failure (e.g., disbond, delamination, crack, tear, etc.). The data can include information about the appearance and progression of a nonconformance over time. The through-thickness reinforcement model generated from the data is a material model for use in finite element analysis.

A through-thickness reinforcement model can be determined from a closed form solution or tabular data. Further, a through-thickness reinforcement model can be implemented as a subroutine that works with a native finite element analysis solver.

FEA 106 is configured to perform finite element analysis on composite structure model 112. FEA 106 can perform finite element analysis using any of a number of different finite element analysis processes that implement numerical methods for solving engineering and mathematical physics problems. FEA 106 can include software such as Abaqus available from Dassault Systemes SE, for example. Performing the finite element analysis can involve applying one or more structural loads, such as a set of structural loads having a range of values applied at different times or a same value applied over time. Example structural loads include a force, a deformation, a temperature, a displacement, a velocity, an acceleration, or a pressure loading.

One example of finite element analysis is modeling failure of a through-thickness reinforcement using a local representative volume model 116. Local representative volume model 116 can include a composite structure having an embedded through-thickness reinforcement. For instance, local representative volume model 116 can include two components of a composite structure, and the through-thickness reinforcement can be a reinforcement that reinforces a connection between the two components. In local representative volume model 116, the through-thickness reinforcement is represented by through-thickness reinforcement model 114. FEA 106 can analyze mechanical performance of local representative volume model 116 as one or more structural loads are applied.

In some examples, during the analysis, while FEA 106 considers the cross-sectional area of the through-thickness reinforcement, the through-thickness reinforcement is not explicitly modeled. In other words, the through-thickness reinforcement does not interact with the host component, such as a stringer or skin panel.

Based on the modeling of the local representative volume model 116, experimental data, or both, analytical material properties indicative of an effective fracture behavior of the through-thickness reinforcement are determined. The analytical material properties can include a penalty stiffness, a cohesive strength, and a strain energy release rate. In some examples, FEA 106 repeats this process for various configurations of the through-thickness reinforcement. For instance, an operator can specify different types or features of the through-thickness reinforcement (e.g., thread type, orientation, etc.) using input system 108, and FEA 106 can generate data modeling failure of the through-thickness reinforcement.

In some examples, based on the modeling of the through-thickness reinforcement using local representative volume model 116, an operator can homogenize the effective fracture behavior into a cohesive zone model. For instance, an operator can provide data defining a cohesive formulation 118 that is representative of the through-thickness reinforcement. A cohesive formulation is a force displacement relationship which is governed by the penalty stiffness, cohesive strength, and strain energy release rate and intended to model disbond within a continuum. The penalty stiffness is meant to be as stiff as possible without affecting the global stiffness such that when a critical strength is reached, it begins to soften by following an unloading curve. This force-displacement relationship can be implemented with a finite thickness element (e.g. to model an adhesive), a zero-thickness cohesive element (e.g. delamination), or as a contact (describing behavior between two solids, i.e. friction). As such, the data defining the cohesive formulation is derived from the analytical material properties.

In one example, cohesive formulation 118 is coded into a cohesive element of a finite element model 120 that can subsequently be analyzed by FEA 106. For instance, the data defining the cohesive formulation can include data specifying a traction-separation response of the through-thickness reinforcement. The data specifying the traction-separation response can include data specifying an N-linear traction-separation curve.

Finite element model 120 is a composite structure model. However, finite element model 120 differs from composite structure model 112 in that the through-thickness reinforcement is represented by three-dimensional elements in composite structure model 112, whereas, the through-thickness reinforcement is represented by cohesive formulation 118 in finite element model 120. One benefit of utilizing this cohesive formulation approach is that the approach can accurately capture crack progression with drastically fewer degrees of freedom as compared to the degrees of freedom involved when preforming a finite element analysis on local representative volume model 116.

In some examples, based on input provided by way of input system 108, a size of cohesive formulation 118 can be scaled based on a proposed planer representation of the through-thickness reinforcement.

FEA 106 is also configured to analyze mechanical performance of finite element model 120. After analyzing the mechanical performance of finite element model 120, FEA 106 can output data indicative of the mechanical performance. For instance, FEA 106 can output results indicating whether the mechanical performance meets a desired performance level. The desired performance level can be based on at least one of a standard, manufacturer specification, federal aviation administration regulations, certification requirements, or other suitable sources for selecting or setting a desired performance level. For instance, analyzing mechanical performance of finite element model 120 can involve demonstrating a fail-safe damage arrest behavior of the composite structure or a slow damage growth behavior of the composite structure.

An operator can adjust characteristics of the through-thickness reinforcement(s) within finite element model 120. For instance, an operator can adjust a type of the through-thickness reinforcement or a property of the through-thickness reinforcement, such as a thread type of a stitch, an orientation or location of the through-thickness reinforcement, a size of the through-thickness reinforcement, etc., so as to generate modified finite element model that FEA 106 can subsequently analyze. The operator can then compare data output by FEA 106 for the modified finite element model with the data output by FEA 106 for a previous finite element model as part of an evaluation, investigation, or optimization process.

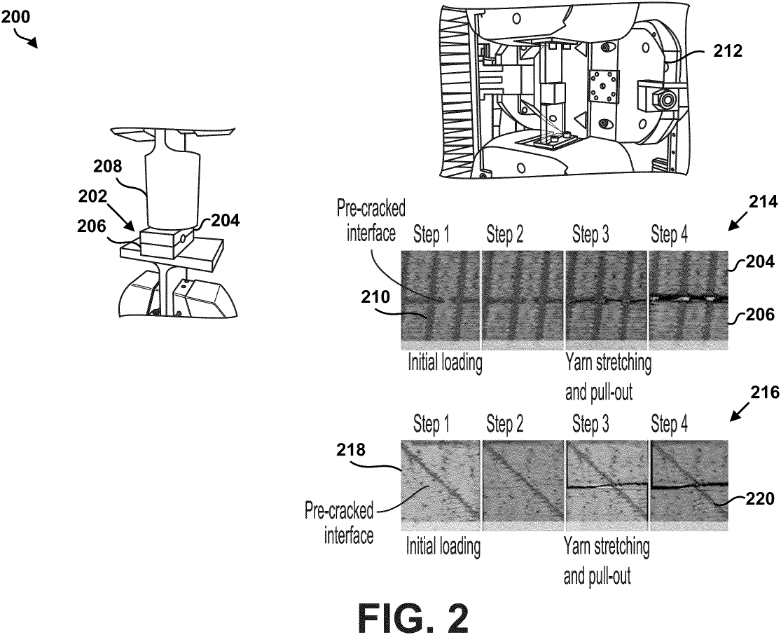

FIG. 2 is a conceptual illustration 200 of flatwise tension testing and associated data. As shown in FIG. 2, with flatwise tension testing, a sample 202 having a first part 204 and a second part 206 that is coupled to first part 204 is placed in a testing machine 208. An interface between first part 204 and second part 206 is reinforced using a through-thickness reinforcement 210. In operation, testing machine 208 applies a tensile load to the sample 202 in a direction normal to the interface between first part 204 and second part 206. The tensile load is applied to pull first part 204 apart from second part 206. Conducting this flatwise testing allows for evaluating the cohesive strength, strain to failure, displacement to failure, and in-situ identification of the hidden failure modes (stitch disbond, the effective length of the stitch involved in the deformation process, stitch rupture, stitch deformation mechanics) of various through-thickness reinforcements, such as various stitch patterns, materials, and architectures, as the through-thickness reinforcements are loaded. In some examples, an operator defines a penalty stiffness that ensures the numeric stiffness does not affect the overall model stiffness. For instance, a computing device or an operator can determine the penalty stiffness by applying a factor of 10, 100, or 1000 to a flatwise tension experimental stiffness to determine the penalty stiffness.

As further shown in FIG. 2, a CT machine 212 can capture experimental data while sample 202 undergoes flatwise tension testing. In particular, CT machine 212 captures in-situ experimental data while a load frame is used to apply load to sample 202. The in-situ experimental data captures the underlying damage and deformation mechanics to characterize the hidden modes occurring within sample 202 under load. The use of CT machine 212 to capture in-situ experimental data is advantageous for developing an accurate material model. CT machine 212 can generate a first set of images 214 of sample 202. First set of images 214 depicts the hidden deformation and failure behavior of through-thickness reinforcement 210 during various steps of the testing. For instance, first set of images 214 includes respective images for step 1 (initial loading), step 2 (further loading), step 3 (yarn stretching and pull-out), and step four (yarn rupture). Similarly, FIG. 2 shows a second set of images 216 for a different sample 218 having another through-thickness reinforcement 220.

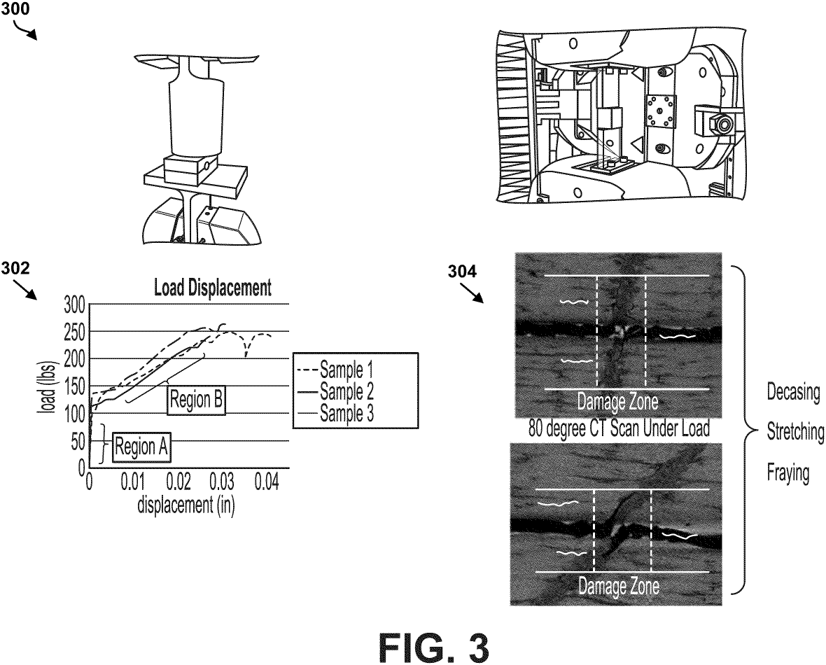

FIG. 3 is a conceptual illustration 300 of compiled flatwise tension data. As shown in FIG. 3, load displacement data 302, indicative of interlaminar tension behavior of various stitch patterns, is derived from flatwise tension testing. In addition, analyzing in-situ CT data 304 allows for understanding the underlying fundamental damage mechanisms driving stitch behavior. These mechanisms include decasing, stretching, and fraying. Decasing occurs during initial loading (Region A highlighted within load displacement data 302). For instance, a through-thickness stretch may uncoil prior to being engaged. Stretching occurs during subsequent loading after the stitch engages (Region B highlighted within load displacement data 302).

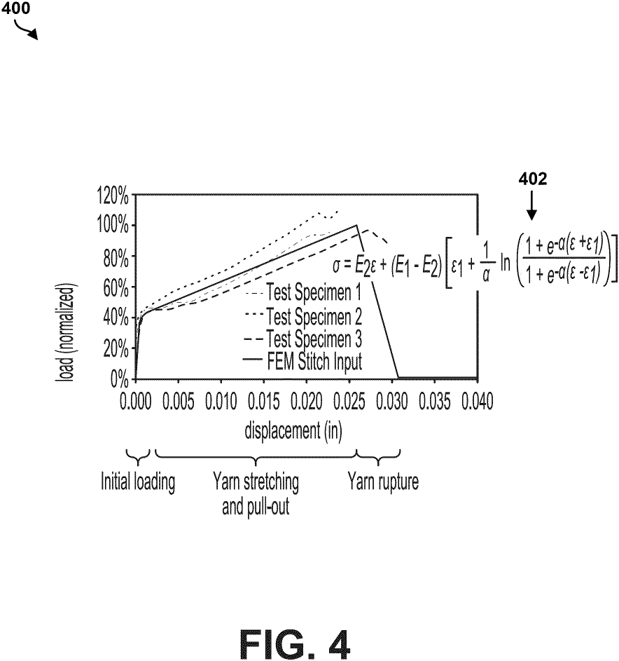

Gathering and compiling flatwise tension testing data facilitates the generation of a stitch behavior model. FIG. 4 is a conceptual illustration 400 of a stitch behavior model 402. In FIG. 4, stitch behavior model 402 is represented by an expression that captures the response of a stitch to loading. Values for coefficients within the expression can be established by fitting the expression to flatwise tension experimental data.

In some examples, stitch behavior models for different through-thickness reinforcements can be used to generate through-thickness reinforcement models for use in finite element analysis within a local representative volume model, such as through-thickness reinforcement model 114 of FIG. 1.

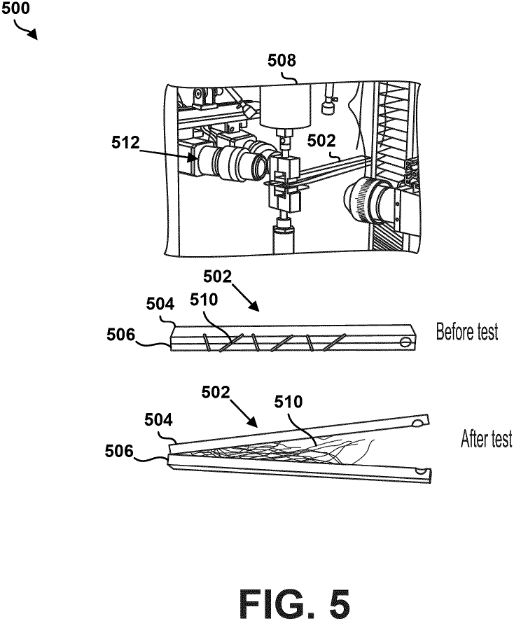

FIG. 5 is a conceptual illustration 500 of fracture toughness testing. As shown in FIG. 5, with fracture toughness testing, a sample 502 having a first part 504 and a second part 506 that is coupled to first part 504 is placed in a testing machine 508. An interface between first part 504 and second part 506 is reinforced using a through-thickness reinforcement 510. Sample 502 also includes an embedded through-width insert (debond) (not shown in FIG. 5). In operation, testing machine 508 applies a double cantilever beam test to sample 502. As part of the double cantilever beam test, a tensile load is applied to sample 502. The tensile load pulls first part 504 away from second part 506 at a first end of sample 502. During the course of the test, the tensile load causes a crack within sample 502 to lengthen. The length of the crack is measured using one or more cameras 512 of testing machine.

The double cantilever beam test yields mode I fracture behavior experimental data. In mode I, the fracture plane is perpendicular to the normal force due to the tensile load. In some examples, additional fracture toughness testing is carried out to generate mode II fracture behavior experimental data. In mode II, fracture occurs under the action of shear stress and propagates in the direction of the crack plane/coupon length. One example of a test for generating mode II fracture behavior is an end notch flexure test. Conducting fracture toughness testing allows for evaluating the fracture behavior and crack propagation of various through-thickness reinforcements, such as various stitch patterns, materials, and architectures.

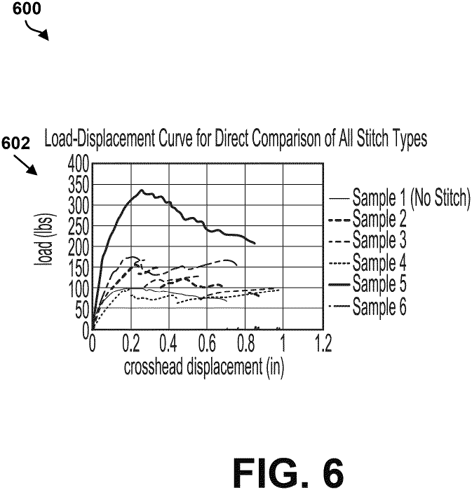

FIG. 6 is a conceptual illustration 600 of compiled fracture toughness data. As shown in FIG. 6, load displacement data 602, indicative of fracture behavior of various stitch patterns, is derived from fracture toughness testing. Gathering and compiling fracture toughness testing data facilitates the generation of an effective stitch response model that represents a strain energy release rate.

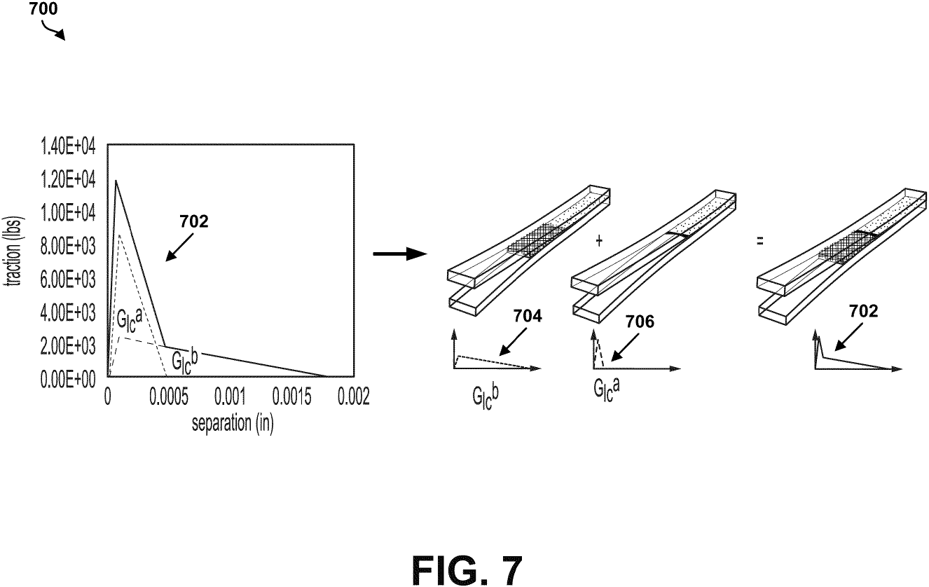

FIG. 7 is a conceptual illustration 700 of an effective stitch response model 702. Effective stitch response model 702 characterizes the strain energy release rate of a through-thickness reinforcement. For instance, effective stitch response model 702 characterizes the strain energy release rate of an interface that is reinforced by the through-thickness reinforcement.

As shown in FIG. 7, effective stitch response model 702 combines a first strain energy release rate of an unreinforced interface

$${G}_{I c} {}^{a}$$

(e.g., without the through-thickness reinforcement) and a second strain energy release rate of the through-thickness reinforcement itself

$${G}_{I c} {}^{b}$$

to define a traction-separation response. Effective stitch response model 702 is composed of a first bi-linear model 704 and a second bi-linear model 706 which are superimposed to create effective stitch response model 702. Effective stitch response model 702, first bi-linear model 704, and second bi-linear model 706 are all collocated at the same nodes.

Advantageously, effective stitch response model 702 can be used to represent a through-thickness reinforcement within a finite element model. For example, effective stitch response model 702 can be used to define a cohesive formulation for use by a FEA during finite element analysis. The cohesive formulation can include a finite thickness element (e.g. to model an adhesive), a zero-thickness cohesive element (e.g. delamination), or a contact (describing behavior between two solids, think of like modeling friction).

In some examples, data defining the cohesive formulation can include data specifying a traction-separation response of the through-thickness reinforcement. For instance, data defining the cohesive formulation can include data specifying an N-linear (e.g., tri-linear) traction-separation response. The data can include one or more expressions, tabular data, or a function. Data defining the cohesive formulation can also be derived from other analytical material properties of the through-thickness reinforcement, such as penalty stiffness and cohesive strength. In some instances, the cohesive formulation is be implemented as a subroutine that works with a native finite element analysis solver. The analytical material parameters of penalty stiffness, cohesive strength, and the strain energy release rates and/or traction-separation response can be used when defining the subroutine.

Further, characterizing the through-thickness reinforcement using a cohesive formulation allows for scaling a size of the cohesive formulation based on a proposed planar representation of the through-thickness reinforcement. For instance, the use of cohesive formulations provides the ability to scale based on structural application requirements from micro to meso to macro structure scales. As an example, a cohesive formulation can be scaled as desired to facilitate analysis of a finite element model that represents multiple different parts of an aircraft.

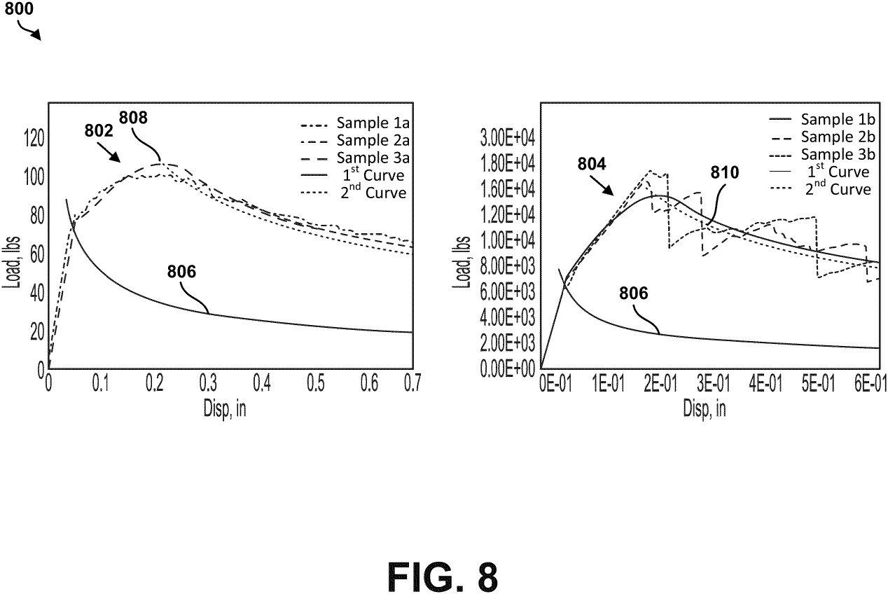

FIG. 8 is a conceptual illustration 800 of accuracies of different effective stitch response models. In particular, FIG. 8 shows first traction-separation experimental data 802 for a first through-thickness reinforcement and second traction-separation experimental data 804 for a second through-thickness reinforcement. A first curve 806 and a second curve 808 are superimposed over first traction-separation experimental data 802. First curve 806 and second curve 808 are analytical traction-separation responses for two different values of strain energy release rates

$${G}_{I c} {}^{b} .$$

As demonstrated by the similarities between second curve 808 and first traction-separation data, the value of the strain energy release rate for second curve 808, and hence the corresponding effective stitch response model, accurately captures crack progression for the first through-thickness reinforcement.

Similarly, a third curve 810 depicts an analytical traction-separation response for another value of strain energy release rates

$${G}_{I c} {}^{b} .$$

As demonstrated by the similarities between third curve 810 and second traction-separation experimental data 804, the value of the strain energy release rate for third curve 810, and hence the corresponding effective stitch response model, accurately captures crack progression for the second through-thickness reinforcement. Hence, FIG. 8 demonstrates that a cohesive formulation calibrated by the underlying experimental data and/or analytical data can be highly accurate for both unstitched and stitched conditions.

Although portions of the descriptions of FIGS. 2-8 refer to through-thickness stitching, the examples are not meant to be limiting. The features, approaches, and explanations are equally applicable to other types of through-thickness reinforcements from nano/micro through macro length scales.

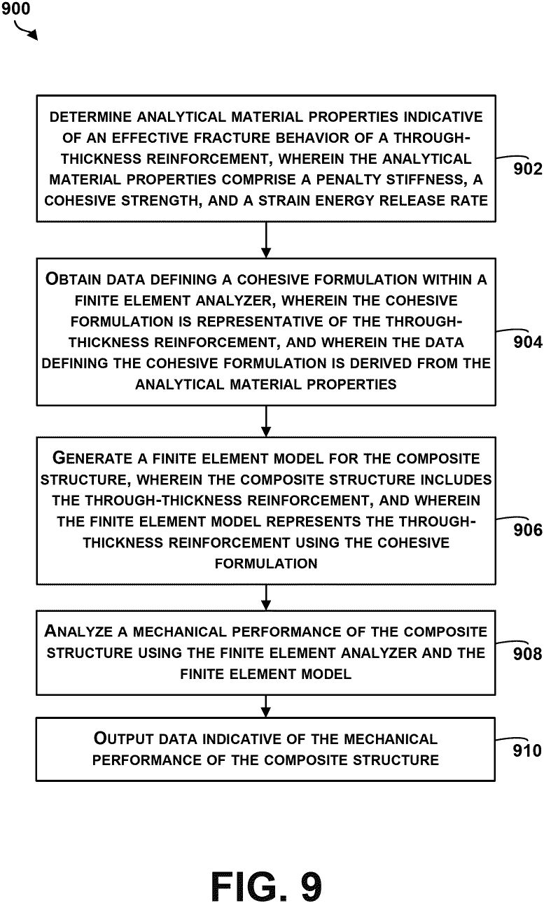

FIG. 9 shows a flowchart of a method 900, according to an example. Method 900 shown in FIG. 9 presents an embodiment of a method that, for example, could be used with any of the systems disclosed herein. Any of the computing systems described herein, such as computing system 100 of FIG. 1, may be used or configured to perform logical functions presented in FIG. 9.

Method 900 can include one or more operations, functions, or actions as illustrated by one or more of blocks 902-912. Although these blocks are illustrated in a sequential order, these blocks may also be performed in parallel, and/or in a different order than those described herein. Also, the various blocks may be combined into fewer blocks, divided into additional blocks, and/or removed based upon the desired implementation.

It should be understood that for this and other processes and methods disclosed herein, flowcharts show functionality and operation of one possible implementation of present embodiments. In this regard, each block may represent a module, a segment, or a portion of program code, which includes one or more instructions executable by a processor for implementing specific logical functions or steps in the process. The program code may be stored on any type of computer readable medium or data storage, for example, such as a storage device including a disk or hard drive. The computer readable medium may include non-transitory computer readable medium or memory, for example, such as computer readable media that stores data for short periods of time like register memory, processor cache, and RAM. The computer readable media may also be any other volatile or non-volatile storage systems. The computer readable medium may be considered a tangible computer readable storage medium, for example.

Initially, at block 902, method 900 includes determining analytical material properties indicative of an effective fracture behavior of a through-thickness reinforcement. The analytical material properties include a penalty stiffness, a cohesive strength, and a strain energy release rate. At block 904, method 900 includes obtaining data defining a cohesive formulation within a FEA. The cohesive formulation is representative of the through-thickness reinforcement, and the data defining the cohesive formulation is derived from the analytical material properties. At block 906, method 900 includes generating a finite element model for the composite structure. The composite structure includes the through-thickness reinforcement, and the finite element model represents the through-thickness reinforcement using the cohesive formulation. At block 908, method 900 includes analyzing a mechanical performance of the composite structure using the FEA and the finite element model. And at block 910, method 900 includes outputting data indicative of the mechanical performance of the composite structure.

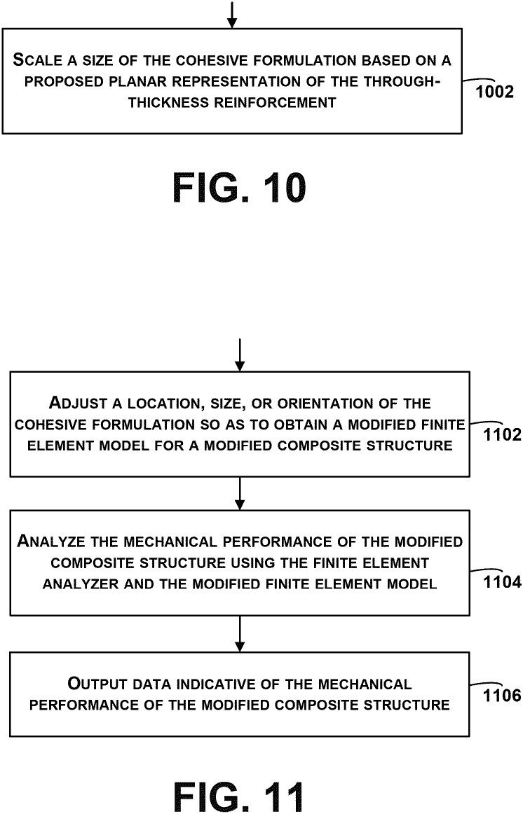

FIG. 10 shows an additional operation for use with the method shown in FIG. 9. Block 1002 could be performed as part of block 906 of FIG. 9. At block 1002, FIG. 10 includes scaling a size of the cohesive formulation based on a proposed planar representation of the through-thickness reinforcement.

FIG. 11 shows additional operations for use with the method shown in FIG. 9. Blocks 1102, 1104, and 1106 could be performed after block 910 of FIG. 9. At block 1102, FIG. 11 includes adjust a location, size, or orientation of the cohesive formulation so as to obtain a modified finite element model for a modified composite structure. At block 1104, FIG. 11 includes analyze the mechanical performance of the modified composite structure using the FEA and the modified finite element model. And at block 1106, FIG. 11 includes outputting data indicative of the mechanical performance of the modified composite structure.

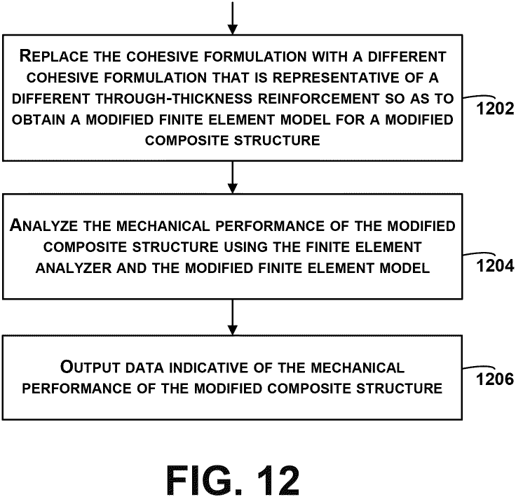

FIG. 12 shows additional operations for use with the method shown in FIG. 9. Blocks 1202, 1204, and 1206 could be performed after block 910 of FIG. 9. At block 1202, FIG. 12 includes replacing the cohesive formulation with a different cohesive formulation that is representative of a different through-thickness reinforcement so as to obtain a modified finite element model for a modified composite structure. At block 1204, FIG. 12 includes analyze the mechanical performance of the modified composite structure using the FEA and the modified finite element model. And at block 1206, FIG. 12 includes outputting data indicative of the mechanical performance of the modified composite structure.

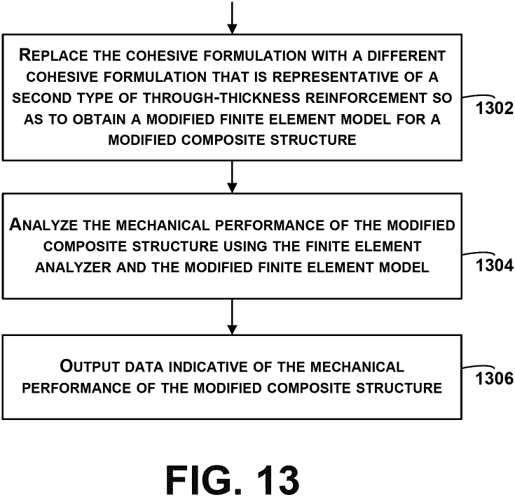

FIG. 13 shows additional operations for use with the method shown in FIG. 9. Blocks 1302, 1304, and 1306 could be performed after block 910 of FIG. 9 in an example in which the through-thickness reinforcement is representative of a first type of through-thickness reinforcement. At block 1302, FIG. 13 includes replacing the cohesive formulation with a different cohesive formulation that is representative of a second type of through-thickness reinforcement so as to obtain a modified finite element model for a modified composite structure. At block 1304, FIG. 13 includes analyze the mechanical performance of the modified composite structure using the FEA and the modified finite element model. And at block 1306, FIG. 13 includes outputting data indicative of the mechanical performance of the modified composite structure.

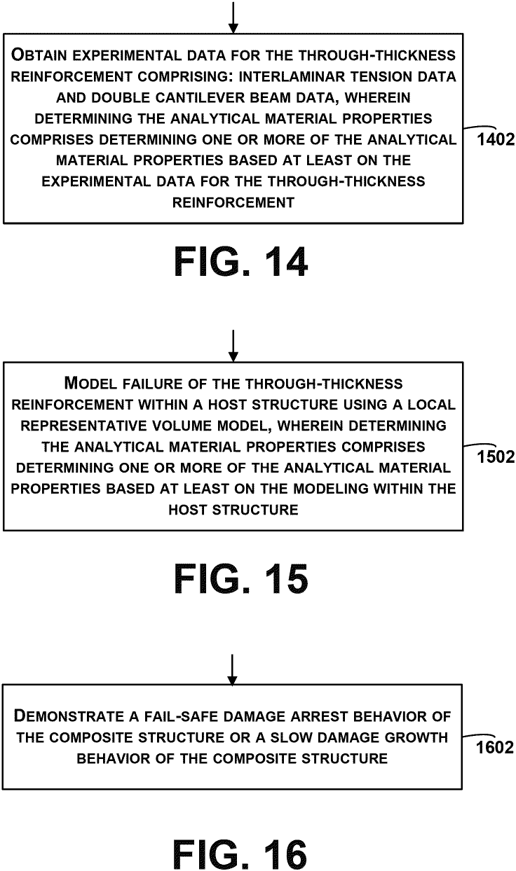

FIG. 14 shows an additional operation for use with the method shown in FIG. 9. Block 1402 could be performed as part of block 902 of FIG. 9. At block 1402, FIG. 14 includes obtaining experimental data for the through-thickness reinforcement including: interlaminar tension data and double cantilever beam data. One or more of the analytical material properties determined at block 902 are based on the experimental data for the through-thickness reinforcement.

FIG. 15 shows an additional operation for use with the method shown in FIG. 9. Block 1502 could be performed as part of block 908 of FIG. 9. At block 1502, FIG. 15 includes demonstrating a fail-safe damage arrest behavior of the composite structure or a slow damage growth behavior of the composite structure.

FIG. 16 shows an additional operation for use with the method shown in FIG. 9. Block 1602 could be performed as part of block 902 of FIG. 9. At block 1602, FIG. 16 includes modeling failure of the through-thickness reinforcement within a host structure using a local representative volume model. One or more of the analytical material properties determined at block 902 are based on the modeling within the host structure.

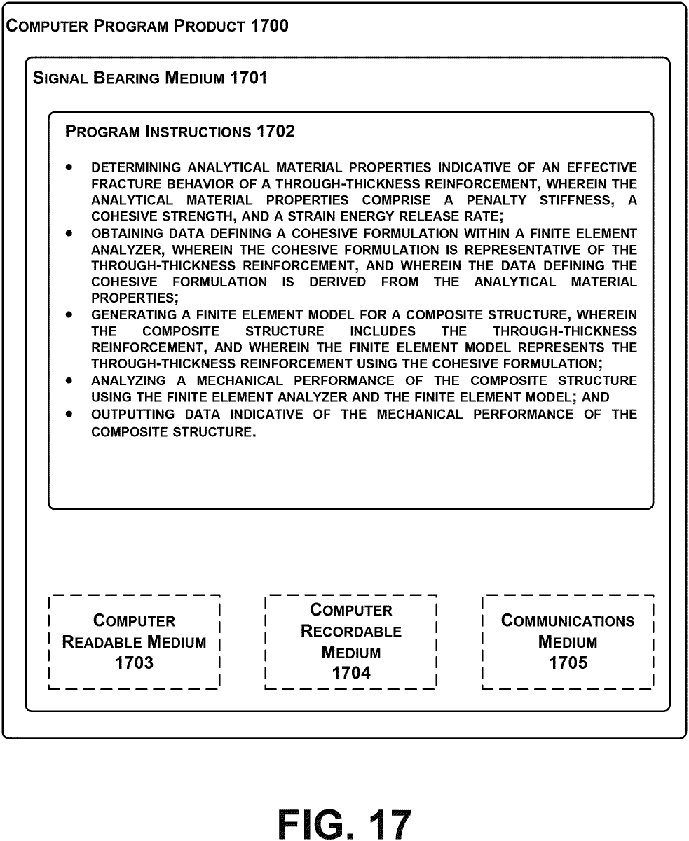

In some embodiments, one or more of the disclosed functions may be implemented as computer program instructions encoded on a non-transitory computer-readable storage media in a machine-readable format, or on other non-transitory media or articles of manufacture. FIG. 17 is a schematic illustrating a conceptual partial view of an example computer program product 1700 that includes a computer program for executing a computer process on a computing device, arranged according to at least some embodiments presented herein. In one embodiment, the example computer program product 1700 is provided using a signal bearing medium 1701. The signal bearing medium 1701 may include one or more programming instructions 1702 that, when executed by one or more processors may provide functionality or portions of the functionality described above with respect to FIGS. 1-16. Thus, for example, referring to the embodiments shown in FIG. 9, one or more features of blocks 902-910 may be undertaken by one or more instructions associated with the signal bearing medium 1701.

In some examples, the signal bearing medium 1701 may encompass a computer-readable medium 1703, such as, but not limited to, a hard disk drive, a Compact Disc (CD), a Digital Video Disk (DVD), a digital tape, memory, etc. In some implementations, the signal bearing medium 1701 may encompass a computer recordable medium 1704, such as, but not limited to, memory, read/write (R/W) CDs, R/W DVDs, etc. In some implementations, the signal bearing medium 1701 may encompass a communications medium 1705, such as, but not limited to, a digital and/or an analog communication medium (e.g., a fiber optic cable, a waveguide, a wired communications link, a wireless communication link, etc.). Thus, for example, the signal bearing medium 1701 may be conveyed by a wireless form of the communications medium 1705 (e.g., a wireless communications medium conforming with the IEEE 802.11 standard or other transmission protocol).

The one or more programming instructions 1702 may be, for example, computer executable and/or logic implemented instructions. In some examples, a computing system such as computing system 100 of FIG. 1 may be configured to provide various operations, functions, or actions in response to the programming instructions 1702 conveyed to the computing system 100 by one or more of the computer-readable medium 1703, the computer recordable medium 1704, and/or the communications medium 1705.

The description of the different advantageous arrangements has been presented for purposes of illustration and description, and is not intended to be exhaustive or limited to the examples in the form disclosed. After reviewing and understanding the foregoing disclosure, many modifications and variations will be apparent to those of ordinary skill in the art. Further, different examples may provide different advantages as compared to other examples. The example or examples selected are chosen and described in order to best explain the principles, the practical application, and to enable others of ordinary skill in the art to understand the disclosure for various examples with various modifications as are suited to the particular use contemplated.

What is claimed is:

1. A method for designing a composite structure, the method comprising:
determining analytical material properties indicative of an effective fracture behavior of a through-thickness reinforcement, wherein the analytical material properties comprise a penalty stiffness, a cohesive strength, and a strain energy release rate;
obtaining data defining a cohesive formulation within a finite element analyzer, wherein the cohesive formulation is representative of the through-thickness reinforcement, and wherein the data defining the cohesive formulation is derived from the analytical material properties;
generating a finite element model for the composite structure, wherein the composite structure includes the through-thickness reinforcement, and wherein the finite element model represents the through-thickness reinforcement using the cohesive formulation;
analyzing a mechanical performance of the composite structure using the finite element analyzer and the finite element model; and
outputting data indicative of the mechanical performance of the composite structure.

2. The method of claim 1, further comprising modeling failure of the through-thickness reinforcement within a host structure using a local representative volume model, wherein the determining the analytical material properties comprises determining one or more of the analytical material properties based at least on the modeling within the host structure.

3. The method of claim 1, wherein: generating the finite element model comprises scaling a size of the cohesive formulation based on a proposed planar representation of the through-thickness reinforcement.

4. The method of claim 1, further comprising:
adjusting a location, size, or orientation of the cohesive formulation so as to obtain a modified finite element model for a modified composite structure;
analyzing the mechanical performance of the modified composite structure using the finite element analyzer and the modified finite element model; and
outputting data indicative of the mechanical performance of the modified composite structure.

5. The method of claim 1, further comprising:
replacing the cohesive formulation with a different cohesive formulation that is representative of a different through-thickness reinforcement so as to obtain a modified finite element model for a modified composite structure;
analyzing the mechanical performance of the modified composite structure using the finite element analyzer and the modified finite element model; and
outputting data indicative of the mechanical performance of the modified composite structure.

6. The method of claim 1, wherein:
the cohesive formulation is representative of a first type of through-thickness reinforcement, and
the method further comprises:
replacing the cohesive formulation with a different cohesive formulation that is representative of a second type of through-thickness reinforcement so as to obtain a modified finite element model for a modified composite structure;
analyzing the mechanical performance of the modified composite structure using the finite element analyzer and the modified finite element model; and
outputting data indicative of the mechanical performance of the modified composite structure.

7. The method of claim 1, further comprising obtaining experimental data for the through-thickness reinforcement comprising: interlaminar tension data and double cantilever beam data, wherein the determining the analytical material properties comprises determining one or more of the analytical material properties based at least on the interlaminar tension data and the double cantilever beam data.

8. The method of claim 1, wherein the data defining the cohesive formulation comprises data specifying a traction-separation response of the through-thickness reinforcement.

9. The method of claim 8, wherein the data specifying the traction-separation response comprises data specifying an N-linear traction-separation curve.

10. The method of claim 1, wherein analyzing the mechanical performance of the composite structure comprises demonstrating a fail-safe damage arrest behavior of the composite structure or a slow damage growth behavior of the composite structure.

11. A computing system configured for performing a set of acts comprising:
determining analytical material properties indicative of an effective fracture behavior of a through-thickness reinforcement, wherein the analytical material properties comprise a penalty stiffness, a cohesive strength, and a strain energy release rate;
obtaining data defining a cohesive formulation within a finite element analyzer, wherein the cohesive formulation is representative of the through-thickness reinforcement, and wherein the data defining the cohesive formulation is derived from the analytical material properties;
generating a finite element model for a composite structure, wherein the composite structure includes the through-thickness reinforcement, and wherein the finite element model represents the through-thickness reinforcement using the cohesive formulation;
analyzing a mechanical performance of the composite structure using the finite element analyzer and the finite element model; and
outputting data indicative of the mechanical performance of the composite structure.

12. The computing system of claim 11, wherein generating the finite element model comprises scaling a size of the cohesive formulation based on a proposed planar representation of the through-thickness reinforcement.

13. The computing system of claim 11, wherein the set of acts further comprises:
adjusting a location, size, or orientation of the cohesive formulation so as to obtain a modified finite element model for a modified composite structure;
analyzing the mechanical performance of the modified composite structure using the finite element analyzer and the modified finite element model; and
outputting data indicative of the mechanical performance of the modified composite structure.

14. The computing system of claim 11, wherein the set of acts further comprises:
replacing the cohesive formulation with a different cohesive formulation that is representative of a different through-thickness reinforcement so as to obtain a modified finite element model for a modified composite structure;
analyzing the mechanical performance of the modified composite structure using the finite element analyzer and the modified finite element model; and
outputting data indicative of the mechanical performance of the modified composite structure.

15. The computing system of claim 11, wherein:
the cohesive formulation is representative of a first type of through-thickness reinforcement, and
the set of acts further comprises:
replacing the cohesive formulation with a different cohesive formulation that is representative of a second type of through-thickness reinforcement so as to obtain a modified finite element model for a modified composite structure;
analyzing the mechanical performance of the modified composite structure using the finite element analyzer and the modified finite element model; and
outputting data indicative of the mechanical performance of the modified composite structure.

16. The computing system of claim 11, wherein the data defining the cohesive formulation comprises data specifying a traction-separation response of the through-thickness reinforcement.

17. The computing system of claim 16, wherein the data specifying the traction-separation response comprises data specifying an N-linear traction-separation curve.

18. The computing system of claim 11, wherein analyzing the mechanical performance of the composite structure comprises demonstrating a fail-safe damage arrest behavior of the composite structure.

19. A non-transitory computer-readable medium having stored therein instructions that are executable to cause a computing system to perform functions comprising:
determining analytical material properties indicative of an effective fracture behavior of a through-thickness reinforcement, wherein the analytical material properties comprise a penalty stiffness, a cohesive strength, and a strain energy release rate;
obtaining data defining a cohesive formulation within a finite element analyzer, wherein the cohesive formulation is representative of the through-thickness reinforcement, and wherein the data defining the cohesive formulation is derived from the analytical material properties;
generating a finite element model for a composite structure, wherein the composite structure includes the through-thickness reinforcement, and wherein the finite element model represents the through-thickness reinforcement using the cohesive formulation;
analyzing a mechanical performance of the composite structure using the finite element analyzer and the finite element model; and
outputting data indicative of the mechanical performance of the composite structure.

20. The non-transitory computer-readable medium of claim 19, wherein generating the finite element model comprises scaling a size of the cohesive formulation based on a proposed planar representation of the through-thickness reinforcement.
